(19) United States
(12) Patent Application Publication
(10) Pub. No.: US 2024/0303407 A1
(43) Pub. Date: Sep. 12, 2024

(54) POWER DISTRIBUTION STRUCTURE, MANUFACTURING METHOD, AND LAYOUT METHOD

(71) Applicant: TAIWAN SEMICONDUCTOR MANUFACTURING COMPANY, LTD., Hsinchu (TW)

(72) Inventors: Wei-Cheng TZENG, Hsinchu (TW); Shih-Wei PENG, Hsinchu (TW); Wei-Cheng LIN, Hsinchu (TW); Jiann-Tyng TZENG, Hsinchu (TW); Guo-Huei WU, Hsinchu (TW); Hui-Zhong ZHUANG, Hsinchu (TW); Lee-Chung LU, Hsinchu (TW); Yung-Chin HOU, Hsinchu (TW)

(21) Appl. No.: 18/446,744

(22) Filed: Aug. 9, 2023

Related U.S. Application Data
(60) Provisional application No. 63/489,075, filed on Mar. 8, 2023.

(51) Int. Cl. G06F 30/392; G06F 30/373; G06F 30/394

(52) U.S. Cl. CPC G06F 30/392; G06F 30/373; G06F 30/394

(57) ABSTRACT

An IC structure includes first and second complementary field-effect transistors (CFETs) positioned in a semiconductor wafer, each of the first and second CFETs including a gate structure extending in a first direction, an n-type channel extending through the gate structure in a second direction perpendicular to the first direction, and a p-type channel extending through the gate structure in the second direction and aligned with the n-type channel in a third direction perpendicular to each of the first and second directions. A metal line extends in the first direction, is aligned with each of the first and second CFETs in the third direction, and is configured to distribute a power supply or reference voltage to each of the first and second CFETs. The metal line is a metal line closest to each of the first and second CFETs along the third direction and extending in the first direction.

### PRIORITY CLAIM

The present application claims the priority of U.S. Provisional Application No. 63/489,075, filed Mar. 8, 2023, which is incorporated herein by reference in its entirety.

### BACKGROUND

The ongoing trend in miniaturizing integrated circuits (ICs) has resulted in progressively smaller devices which consume less power, yet provide more functionality at higher speeds than earlier technologies. Miniaturization has been achieved through design and manufacturing innovations tied to increasingly strict specifications. Various electronic design automation (EDA) tools are used to generate, revise, and verify designs for semiconductor devices while ensuring that design and manufacturing specifications are met.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1D are diagrams of IC layout diagrams and corresponding IC structures, in accordance with some embodiments.

FIG. 2 is a diagram of an IC layout diagram and corresponding IC structure, in accordance with some embodiments.

FIGS. 3A-3C are diagrams of IC layout diagrams and corresponding IC structures, in accordance with some embodiments.

FIGS. 4A and 4B are diagrams of IC layout diagrams and corresponding IC structures, in accordance with some embodiments.

FIGS. 5A-5E are diagrams of IC layout diagrams and corresponding IC structures, in accordance with some embodiments.

FIGS. 6A and 6B are flowcharts of a method of generating an IC layout diagram, in accordance with some embodiments.

FIG. 7 is a flowchart of a method of manufacturing an IC structure, in accordance with some embodiments.

FIG. 8 is a block diagram of an IC design system, in accordance with some embodiments.

FIG. 9 is a block diagram of an integrated circuit (IC) manufacturing system, and an IC manufacturing flow associated therewith, in accordance with some embodiments.

### DETAILED DESCRIPTION

The following disclosure provides many different embodiments, or examples, for implementing different features of the provided subject matter. Specific examples of components, values, operations, materials, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In various embodiments, an integrated circuit (IC) power distribution structure, corresponding manufacturing method, and system and method of generating corresponding IC layout diagrams are directed to power distribution structures including metal lines positioned in a lowest metal layer in which metal lines are aligned with gates of complementary field-effect transistors (CFETs).

In some embodiments, an IC structure, manufacturing method, and layout diagram correspond to first and second CFETs, each of which includes a gate structure extending in a first direction and n-type and p-type channels extending through the gate structure in a second direction perpendicular to the first direction and aligned with each other in a third direction perpendicular to the first and second directions. Frontside and backside metal lines extend in the first direction, are aligned with each of the first and second CFETs in the third direction, and are configured to distribute power supply and reference voltages to each of the first and second CFETs. Each metal line is a corresponding frontside or backside metal line closest to each of the first and second CFETs along the third direction and extending in the first direction.

In some embodiments, a first and/or second CFET is included in a logic cell configured to be compatible with the metal lines by including at least one blocked metal region in which signal connections are prohibited. A cell placement operation of a corresponding IC layout diagram generation method includes selecting logic cells from multiple electrically equivalent (EEQ) cells, e.g., from a cell library, by aligning the blocked metal regions with the metal lines.

By positioning frontside and backside metal lines of power distribution structures in a lowest metal layer in which metal lines are aligned with gates of CFETs, an IC structure is capable of having improved routing flexibility and reduced power distribution parasitic capacitance without area penalty compared to other approaches, e.g., approaches in which power distribution metal lines are positioned in a lowest metal layer and perpendicular to gates of CFETs.

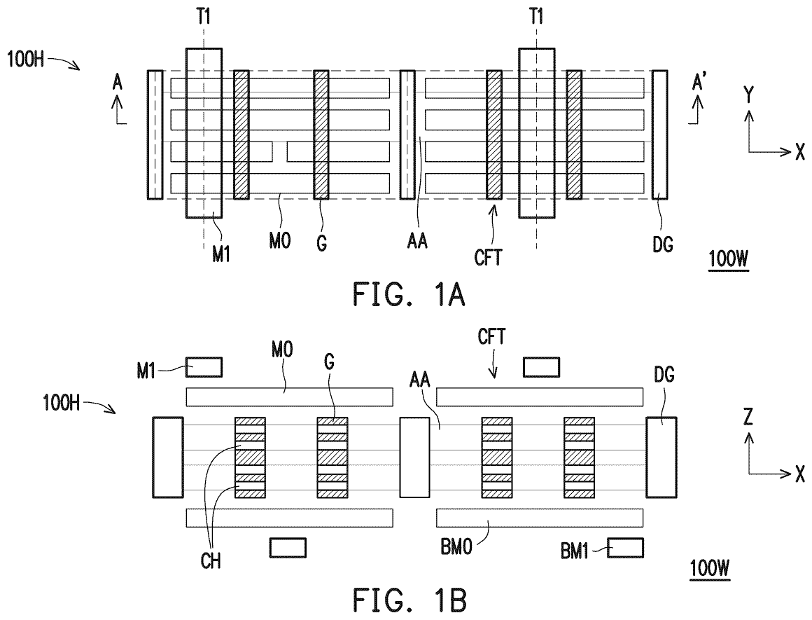

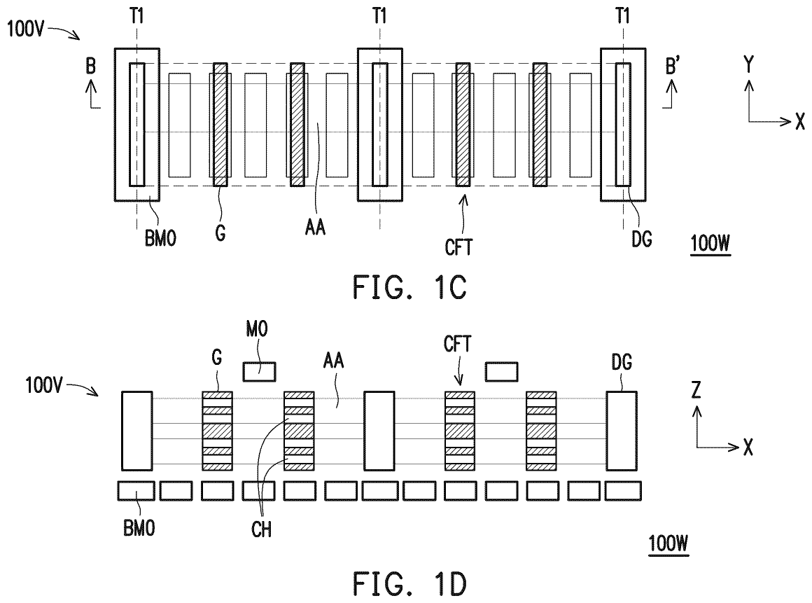

Each of the figures herein, e.g., FIGS. 1A-5E, is simplified for the purpose of illustration. The figures depict IC structures, devices, and layout diagrams with various features included and excluded to facilitate the discussion below. In various embodiments, an IC structure, device and/or layout diagram includes one or more features corresponding to power distribution structures, metal interconnects, contacts, vias, gate structures, source/drain (S/D) structures, bulk connections, or other transistor elements, dielectric layers, isolation structures, or the like, in addition to the features depicted in FIGS. 1A-5E.

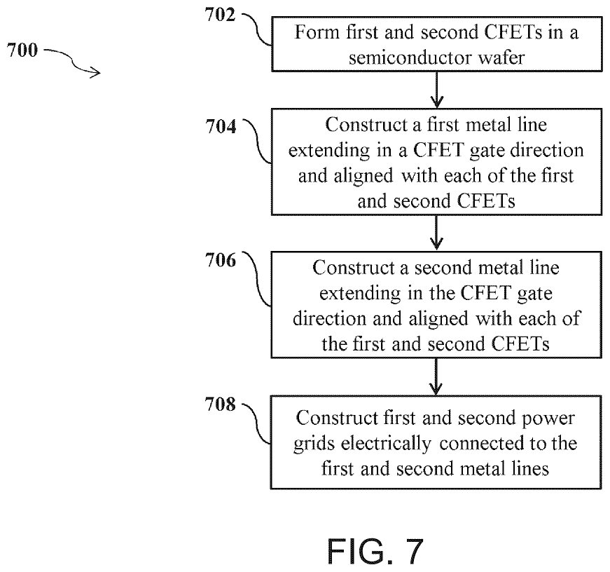

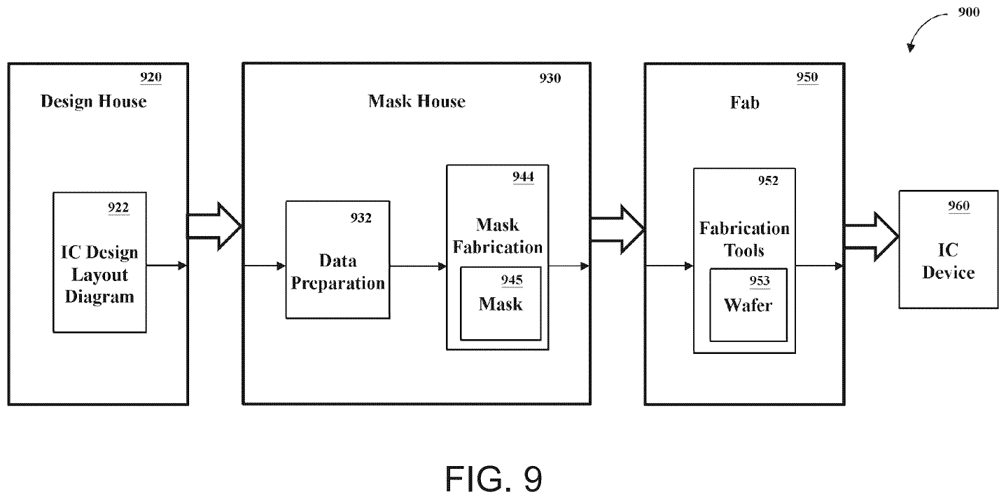

In the IC layout diagrams/structures discussed below, e.g., IC layout diagrams/structures 100H and 100V, reference designators represent both IC structure features and the IC layout features used to at least partially define the corresponding IC structure features in a manufacturing process, e.g., method 700 discussed below with respect to FIG. 7 and/or the IC manufacturing flow associated with IC manufacturing system 900 discussed below with respect to FIG. 9. Accordingly, an IC layout diagram/structure represents a plan or cross-sectional view of both an IC layout diagram and a corresponding IC structure.

FIGS. 1A-1D are diagrams of IC layout diagrams 100H and 100V and corresponding IC structures 100H and 100V positioned in a semiconductor wafer 100W, in accordance with some embodiments. FIG. 1A depicts a plan view of IC layout diagram/structure 100H and X and Y directions; FIG. 1B depicts a cross-sectional view of IC layout diagram/structure 100H along a line A-A′ in FIG. 1A, the X direction, and a Z direction; FIG. 1C depicts a plan view of IC layout diagram/structure 100V and the X and Y directions; and FIG. 1D depicts a cross-sectional view of IC layout diagram/structure 100V along a line B-B′ in FIG. 1C, and the X and Z directions.

Each of IC layout diagrams/structures 100H and 100V includes instances (single ones labeled for the purpose of clarity) of active regions/areas AA extending in the X direction between dummy gate regions/structures DG, gate regions/structures G extending in the Y direction, channels CH extending through corresponding gate regions/structures G, frontside metal regions/lines M1 or M0 extending in the Y direction, e.g., along tracks T1, and backside metal regions/lines BM1 or BM0 extending in the Y direction, e.g., along tracks T1. CFETs CFT correspond to portions of active regions/areas AA adjacent to gate regions/structures G and channels CH and include additional features, e.g., source/drain (S/D) regions/structures, metal-like defined (MD) regions/segments, and/or local interconnects, that are not depicted for the purpose of clarity.

Each of IC layout diagrams/structures 100H and 100V corresponds to an embodiment in which metal regions/lines M1 or M0 are the lowest, e.g., closest to CFETs CFT, frontside metal regions/lines extending in the Y direction, and metal regions/lines BM0 are the lowest, e.g., closest to CFETs CFT, backside metal regions/lines extending in the Y direction.

As depicted in FIGS. 1A and 1B, IC layout diagram/structure 100H includes metal regions/lines M0 and BM0 extending in the X direction and positioned between corresponding metal regions/lines M1 and BM1 and CFETs CFT along the Z direction.

Each of metal regions/lines M0, BM0, M1, and BM1 corresponds to a metal layer (not labelled for the purpose of clarity) of the manufacturing process used to construct IC structure 100H/100V based on IC layout diagram 100H/100V.

In some embodiments, a metal region/line M0 is referred to as a metal zero or first metal region/line M0, a backside metal region/line BM0 is referred to as a backside metal zero or first backside metal region/line BM0, a metal region/line M1 is referred to as a metal one or second metal region/line M1, and/or a backside metal region/line BM1 is referred to as a backside metal one or second backside metal region/line BM1.

As depicted in FIGS. 1A-1D, instances of metal regions/lines M0, BM0, M1, and BM1 are aligned with instances of CFETs CFT along the Z direction. In some embodiments, one or both of IC layout diagrams/structures 100H or 100V includes additional features (not depicted for the purpose of clarity), e.g., via or contact regions/structures, and is thereby configured to provide electrical connections between one or more instances of metal regions/lines M0, BM0, M1, and BM1 and one or more instances of CFETs CFT.

An active region/area, e.g., active region/area AA, is a region in the IC layout diagram included in a manufacturing process as part of defining an active area, also referred to as an oxide diffusion or definition (OD), in the semiconductor substrate, either directly or in an n-well or p-well region/area (not shown for the purpose of clarity), in which one or more IC device features, e.g., a channel CH and/or S/D structure, is formed. In some embodiments, an active area is an n-type or p-type active area of a corresponding n-type or p-type FET of a CFET device. In various embodiments, an active area (structure) includes one or more of a semiconductor material, e.g., silicon (Si), silicon-germanium (SiGe), silicon-carbide (SiC), or the like, a dopant material, e.g., boron (B), phosphorous (P), arsenic (As), gallium (Ga), or another suitable material.

In some embodiments, an active area is a region in an IC layout diagram included in the manufacturing process as part of defining a nano-sheet structure, e.g., a continuous volume of one or more layers of one or more semiconductor materials having either n-type or p-type doping. In some embodiments, a channel portion corresponds to a nano-sheet structure. In various embodiments, individual nano-sheet layers include a single monolayer or multiple monolayers of a given semiconductor material.

A S/D region/structure is a region in the IC layout diagram included in the manufacturing process as part of defining a S/D structure, also referred to as a semiconductor structure in some embodiments, configured to have a doping type opposite that of the corresponding active region/area. In some embodiments, a S/D region/structure is configured to have lower resistivity than an adjacent channel portion. In some embodiments, a S/D region/structure includes one or more portions having doping concentrations greater than one or more doping concentrations present in the corresponding channel portion. In some embodiments, a S/D region/structure includes epitaxial regions of a semiconductor material, e.g., Si, SiGe, and/or silicon-carbide SiC. In some embodiments, a S/D region/structure includes one or more MD regions/segments.

An MD region/segment is a conductive region in the IC layout diagram included in the manufacturing process as part of defining an MD segment, also referred to as a conductive segment or MD conductive line or trace, in and/or on the semiconductor substrate and capable of being electrically connected to an underlying S/D structure and/or underlying and/or overlying via structure. In some embodiments, an MD segment includes a portion of at least one metal layer, e.g., a contact layer, overlying and contacting the substrate and having a thickness sufficiently small to enable formation of an insulation layer between the MD segment and an overlying metal layer, e.g., the first metal layer. In various embodiments, an MD segment includes one or more of copper (Cu), silver (Ag), tungsten (W), titanium (Ti), nickel (Ni), tin (Sn), aluminum (Al) or another metal or material suitable for providing a low resistance electrical connection between IC structure elements, i.e., a resistance level below a predetermined threshold corresponding to one or more tolerance levels of a resistance-based effect on circuit performance.

In various embodiments, an MD segment includes a section of the semiconductor substrate and/or an epitaxial layer having a doping level, e.g., based on an implantation process, sufficient to cause the segment to have the low resistance level. In various embodiments, a doped MD segment includes one or more dopant materials having doping concentrations of about 1*10¹⁶ per cubic centimeter (cm⁻³) or greater.

In some embodiments, a manufacturing process includes two MD layers, and an MD region/segment refers to either or both of the two MD layers in the manufacturing process. In some embodiments, an MD segment is configured to be electrically connected to the S/D structure of a single one of a p-type or n-type FET of a CFET device, and to be electrically isolated from the S/D structure of the other of the p-type or n-type FET of the CFET device. In some embodiments, an MD segment, also referred to as an MD local interconnect (MDLI), local interconnect (LI), or vertical local interconnect (VLI) in some embodiments, is configured to be electrically connected to the S/D structures of both the p-type FET and the n-type FET of a CFET device.

A gate region/structure, e.g., a gate region/structure G, is a region in the IC layout diagram included in the manufacturing process as part of defining a gate structure. A gate structure is a volume including one or more conductive segments, e.g., a gate electrode, including one or more conductive materials, e.g., polysilicon, copper (Cu), aluminum (Al), tungsten (W), cobalt (Co), ruthenium (Ru), or one or more other metals or other suitable materials, substantially surrounded by one or more insulating materials, the one or more conductive segments thereby being configured to control a voltage provided to an adjacent gate dielectric layer.

A dielectric layer, e.g., a gate dielectric layer, is a volume including one or more insulating materials, e.g., silicon dioxide, silicon nitride (Si₃N₄), and/or one or more other suitable material such as a low-k material having a k value less than 3.8 or a high-k material having a k value greater than 3.8 or 7.0 such as aluminum oxide (Al₂O₃), hafnium oxide (HfO₂), tantalum pentoxide (Ta₂O₅), or titanium oxide (TiO₂), suitable for providing a high electrical resistance between IC structure elements, i.e., a resistance level above a predetermined threshold corresponding to one or more tolerance levels of a resistance-based effect on circuit performance.

A dummy gate region/structure, e.g., a dummy gate region/structure DG, also referred to as a poly over OD edge (PODE) region/structure in some embodiments, is a region in the IC layout diagram included in the manufacturing process as part of defining a gate structure at an edge of an active region/area and is thereby configured to electrically isolate the active area from adjacent IC features, e.g., additional active areas.

A metal region/line, e.g., a metal region/line M0, BM0, M1, or BM1, is a region in the IC layout diagram included in the manufacturing process as part of defining a metal line structure including one or more conductive materials, e.g., polysilicon, copper (Cu), aluminum (Al), tungsten (W), cobalt (Co), ruthenium (Ru), or one or more other metals or other suitable materials, in a given metal layer of the manufacturing process.

A via region/structure is a region in the IC layout diagram included in the manufacturing process as part of defining a via structure including one or more conductive materials configured to provide an electrical connection between an overlying conductive structure, e.g., a metal region/line M0, BM0, M1, or BM1, and an underlying conductive structure, e.g., a gate electrode of a gate region/structure G or an MD region/segment of a CFET CFT.

Via regions/structures and metal regions/lines correspond to manufacturing processes used to form features on either a frontside or backside of a semiconductor wafer, e.g., semiconductor wafer 100W.

In the embodiments depicted in FIGS. 1A-1D, a first instance of active region/area AA overlies a second instance of active region/area AA such that CFETs CFT are referred to as stacked CFETs CFT in some embodiments. In various embodiments, CFETs CFT include n-type FETs overlying p-type FETs or p-type FETs overlying n-type FETs.

In the embodiments depicted in FIGS. 1A-1D, instances of gate regions/structure G extend continuously in the Z direction such that a given gate structure G surrounds channels CH of both the p-type and n-type FETs of the corresponding CFET CFT and is thereby configured to simultaneously control both instances of channel CH. In some embodiments, a given gate region/structure G is discontinuous in the Z direction such that separate portions of gate structure G surround each instance of channel CH and are thereby configured to independently control the instances of channel CH.

Frontside metal regions/lines M1 along tracks T1 in IC layout diagram/structure 100H and instances of metal regions/lines M0 in IC layout diagram/structure 100V are configured to distribute one of a power supply voltage, e.g., a voltage VDD discussed below, or a reference voltage, e.g., a ground voltage or a voltage VSS discussed below, to one or more instances of CFETS CFT. Backside instances of metal regions/lines BM1 in IC layout diagram/structure 100H and metal regions/lines BM0 along tracks T1 in IC layout diagram/structure 100V are configured to distribute the other of the power supply voltage or reference voltage.

In some embodiments, frontside metal regions/lines M1 or M0 are configured to distribute the reference voltage, backside metal regions/lines BM1 or BM0 are configured to distribute the power supply voltage, and CFETs CFT include n-type FETs overlying p-type FETs. In some embodiments, frontside metal regions/lines M1 or M0 are configured to distribute the power supply voltage, backside metal regions/lines BM1 or BM0 are configured to distribute the reference voltage, and CFETs CFT include p-type FETs overlying n-type FETs.

Each of IC layout diagrams/structures 100H and 100V is thereby configured to include frontside and backside metal lines M1/M0 and BM1/BM0 of power distribution structures in a lowest metal layer in which metal lines are aligned with gates G of CFETs CFT such that the corresponding IC layout diagram/structure 100H or 100V is capable of having improved routing flexibility and reduced power distribution parasitic capacitance without area penalty compared to other approaches, e.g., approaches in which power distribution metal lines are positioned in a lowest metal layer and perpendicular to gates of CFETs.

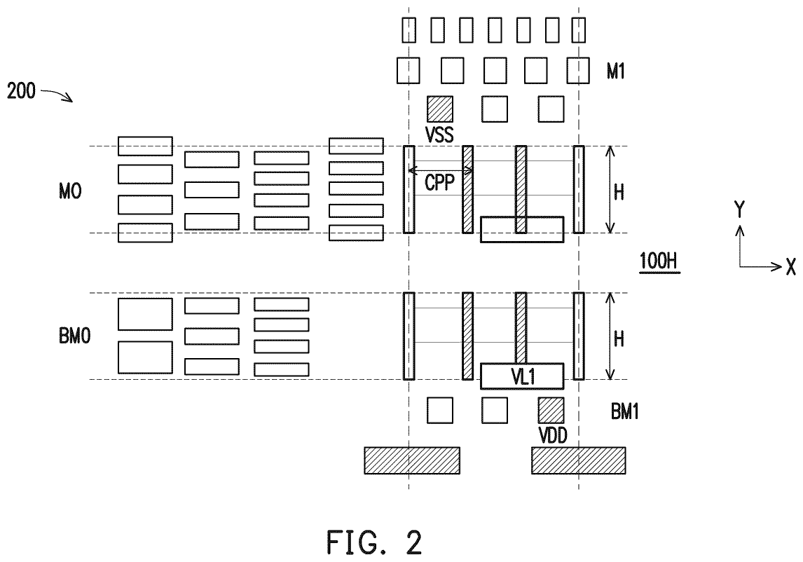

FIG. 2 is a diagram of an IC layout diagram 200 and corresponding IC structure 200, in accordance with some embodiments. IC layout diagram/structure 200 is a plan view of a non-limiting example of IC layout diagram/structure 100H (features not labeled for the purpose of clarity) and the X and Y directions that illustrates various configurations of corresponding frontside and backside metal regions/lines M1/M0 and BM1/BM0. In the embodiment depicted in FIG. 2, IC layout diagram/structure 200 includes a local interconnect region/structure VLI.

As depicted in FIG. 2, IC layout diagram/structure 200 includes instances of gate regions/structures G and dummy gate regions/structures DG having a pitch CPP in the X direction. In some embodiments, pitch CPP is referred to as a gate pitch CPP or a contact poly pitch CPP.

FIG. 2 depicts two perspectives of IC layout diagram/structure 100H corresponding to the frontside and backside of semiconductor wafer 100W, each of which has a cell height H, also referred to as a row height H in some embodiments.

IC layout diagram/structure 200 corresponds to embodiments in which frontside metal regions/lines M0 have one of four pitches in the Y direction, frontside metal regions/lines M1 have one of three pitches in the X direction, backside metal regions/lines BM0 have one of three pitches in the Y direction, and backside metal regions/lines BM1 have one of two pitches in the X direction.

As depicted in FIG. 2, the pitches of frontside metal regions/lines M0 and backside metal regions/lines BM0 correspond to fractions or multiples of cell height H, and the pitches of frontside metal regions/lines M1 and backside metal regions/lines BM1 correspond to pitch CPP or fractions or multiples of pitch CPP.

In an embodiment depicted in FIG. 2, a single instance of frontside metal region/line M1 is positioned over IC layout diagram/structure 100H between instances of gate region/structure G and dummy gate region/structure DG and is configured to distribute reference voltage VSS. In some embodiments, multiple instances of frontside metal region/line M1 are positioned over IC layout diagram/structure 100H, e.g., over instances of dummy gate region/structure DG, and are configured to distribute reference voltage VSS.

In an embodiment depicted in FIG. 2, a single instance of backside metal region/line BM1 is positioned over IC layout diagram/structure 100H between instances of gate region/structure G and dummy gate region/structure DG and is configured to distribute power supply voltage VDD. In some embodiments, multiple instances of backside metal region/line BM1 are positioned over IC layout diagram/structure 100H, e.g., over instances of dummy gate region/structure DG, and are configured to distribute power supply voltage VDD.

The various embodiments of IC layout diagram/structure 200 are thereby configured to include instances of frontside metal region/line M1 and backside metal region/line BM1 configured as discussed above with respect to FIGS. 1A-1D such that IC layout diagram/structure 200 is capable of realizing the benefits discussed above with respect to IC layout diagram/structure 100H.

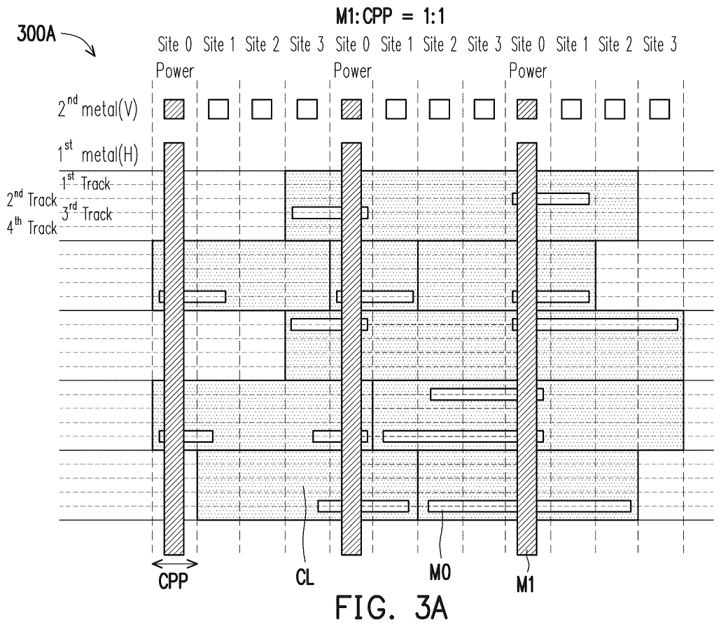

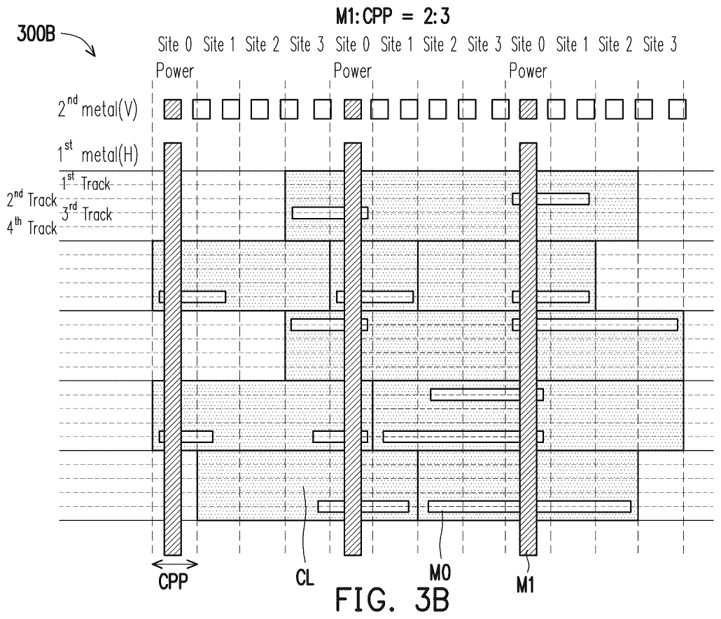

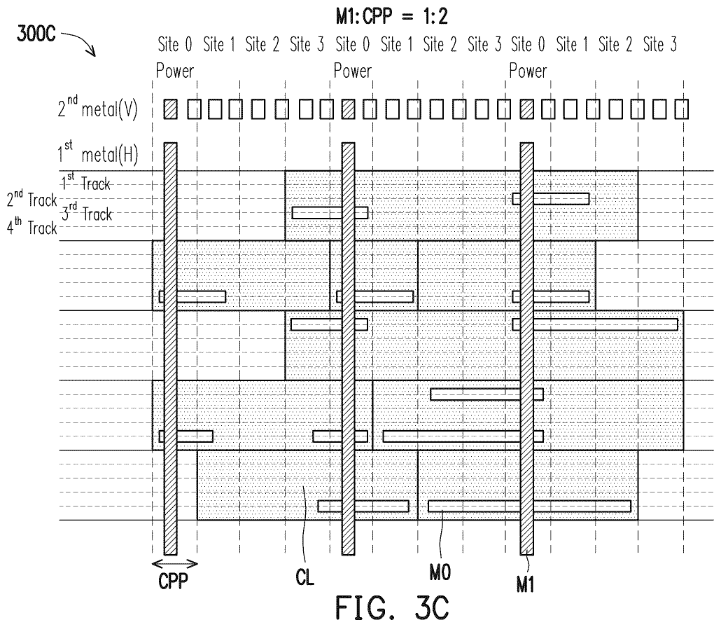

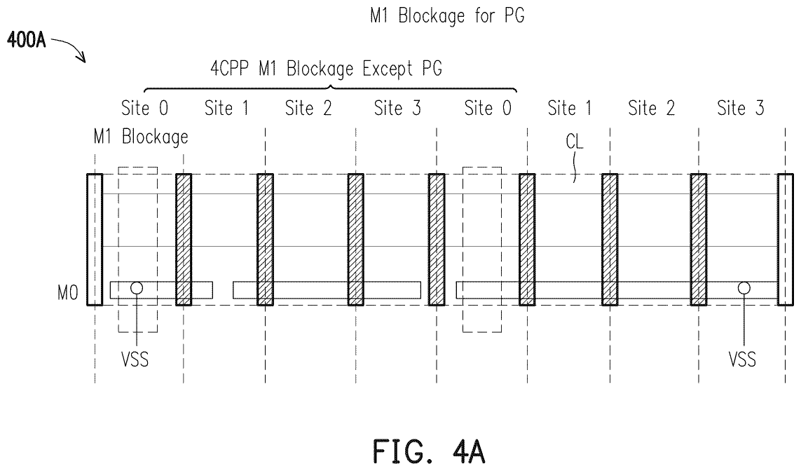

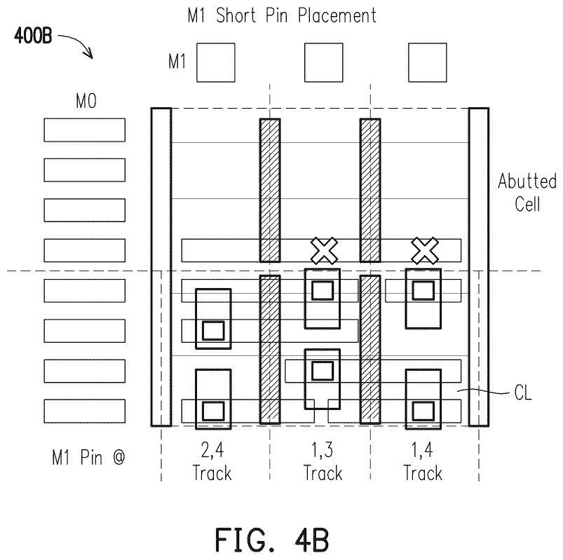

FIGS. 3A-3C are diagrams of IC layout diagrams 300A-300C and corresponding IC structures 300A-300C, in accordance with some embodiments. Each of IC layout diagrams/structures 300A-300C is a non-limiting example including a configuration of frontside metal regions/lines M1 in accordance with an embodiment of IC layout diagram 200 discussed above.

Each of IC layout diagrams/structures 300A-300C includes instances of metal regions/lines M0 and M1 discussed above and five rows of cells CL (a single instance labeled for the purpose of clarity), each of which includes one or more instances of IC layout diagram/structure 100H (not depicted for the purpose of clarity) discussed above. Each of IC layout diagrams/structures 300A-300C corresponds to an embodiment in which frontside metal regions/lines M0 are positioned among one or more along four tracks corresponding to each row.

IC layout diagram/structure 300A includes metal regions/lines M1 having a pitch equal to pitch CPP, IC layout diagram/structure 300B includes metal regions/lines M1 having a pitch ratio of 2:3 relative to pitch CPP, and IC layout diagram/structure 300C includes metal regions/lines M1 having a pitch ratio of 1:2 relative to pitch CPP.

Each of IC layout diagrams/structures 300A-300C includes a subset of instances of metal regions/lines M1 configured to carry a power supply or reference voltage, the subset having a pitch equal to a multiple of pitch CPP.

Because IC layout diagrams/structures 300A-300C include instances of metal regions/lines M0 configured to distribute the power supply or reference voltage to CFETs, e.g., CFETs CFT discussed above, from the subset of instances of metal regions/lines M1, voltage drops based on a metal region/line M0 parasitic resistance increase as the subset to CPP pitch multiple increases.

In the embodiments depicted in FIGS. 3A-3C, each of IC layout diagrams/structures 300A-300C includes the subset to CPP pitch multiple equal to four. In some embodiments, one or more of IC layout diagrams/structures 300A-300C includes the subset to CPP pitch multiple ranging from one to three. In some embodiments, one or more of IC layout diagrams/structures 300A-300C includes the subset to CPP pitch multiple greater than four, e.g., ranging from five to eight.

Each of the embodiments of IC layout diagrams/structures 300A-300C is thereby configured to include instances of frontside metal region/line M1 configured as discussed above with respect to FIGS. 1A-1D such that each of IC layout diagrams/structures 300A-300C is capable of realizing the benefits discussed above with respect to IC layout diagram/structure 100H.

FIGS. 4A and 4B are diagrams of IC layout diagrams 400A and 400B and corresponding IC structures 400A and 400B, in accordance with some embodiments. Each of IC layout diagrams/structures 400A and 400B includes a non-limiting example of cell CL discussed above and is provided for the purpose of illustration.

In the embodiment depicted in FIG. 4A, IC layout diagram 400A includes an instance of cell CL including two instances of regions M1 Blockage, each of which is a region in an IC layout diagram, e.g., a cell CL, in which signal pin placement is excluded, thereby allowing a power supply or reference voltage electrical connection to be made in the corresponding IC structure 400A.

In the embodiment depicted in FIG. 4B, IC layout diagram 400B includes an instance of cell CL including instances of metal regions M1, each of which extends in parallel with instances of gate regions G and dummy gate regions DG (not labeled for the purpose of clarity) along a distance less than a height of cell CL and is thereby configured to be usable as a signal pin and allowing signal pin electrical connections to be made in the corresponding IC structure 400B.

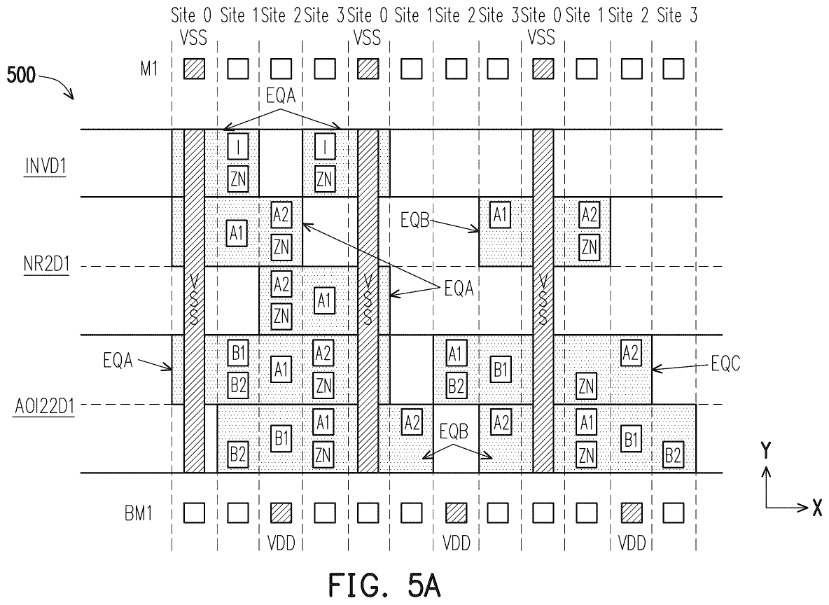

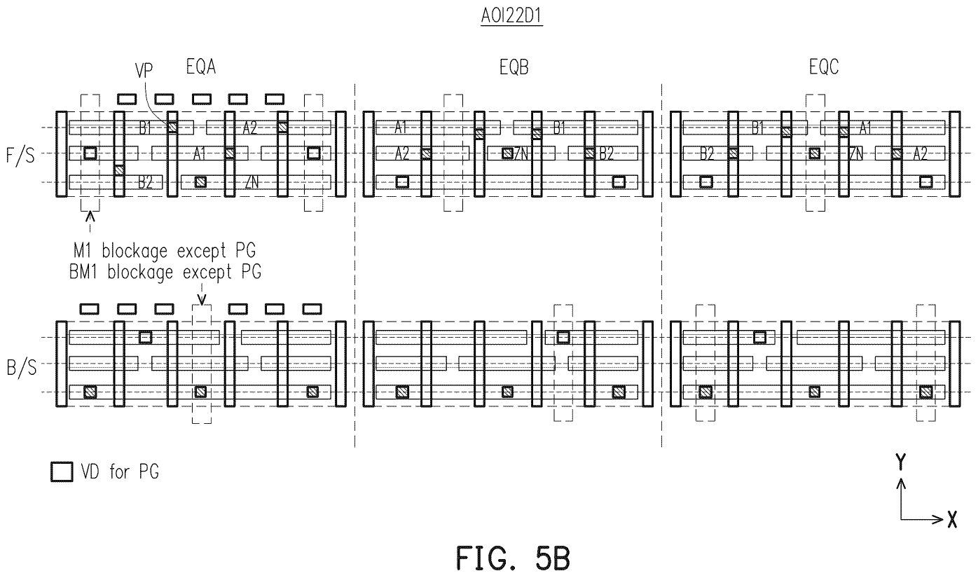

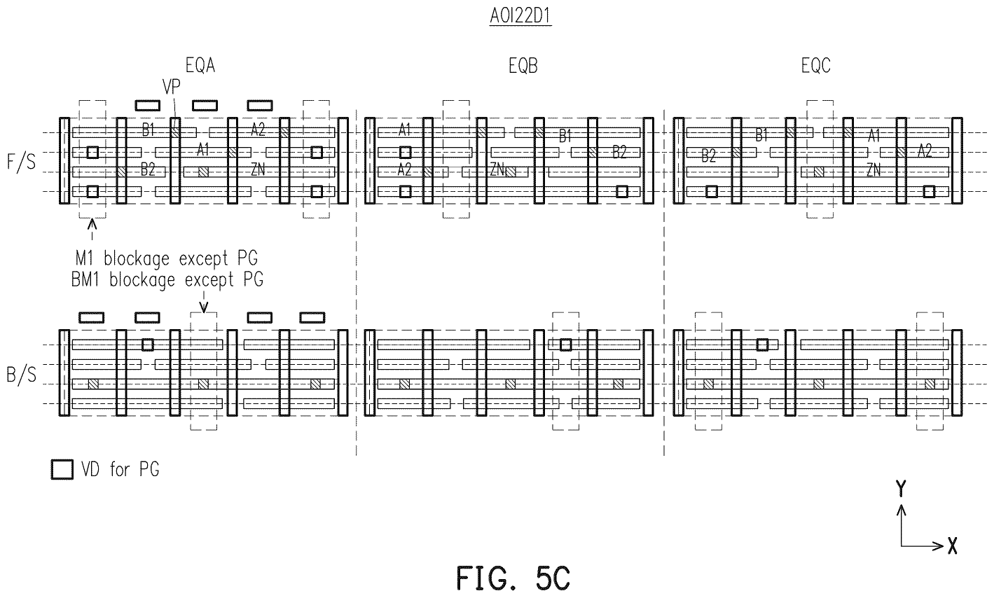

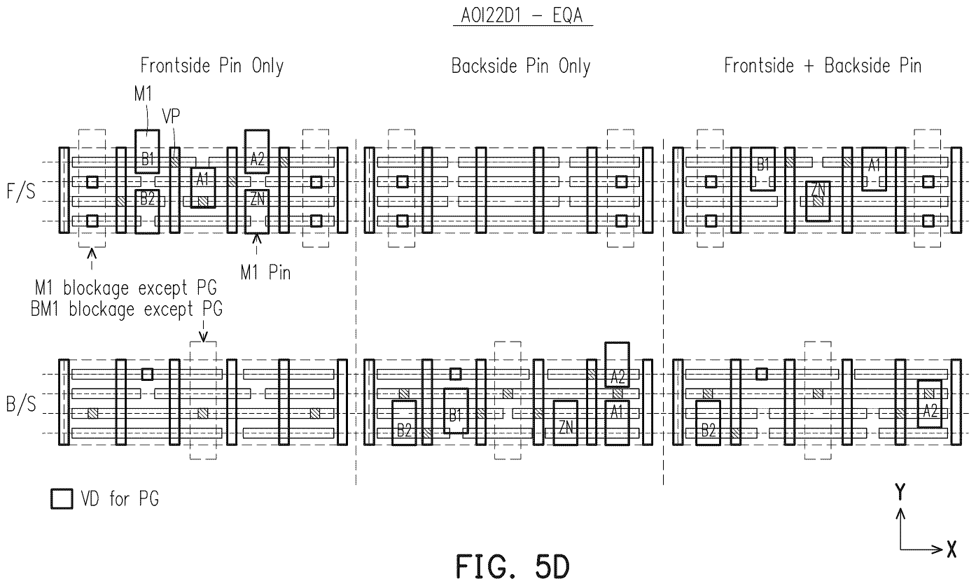

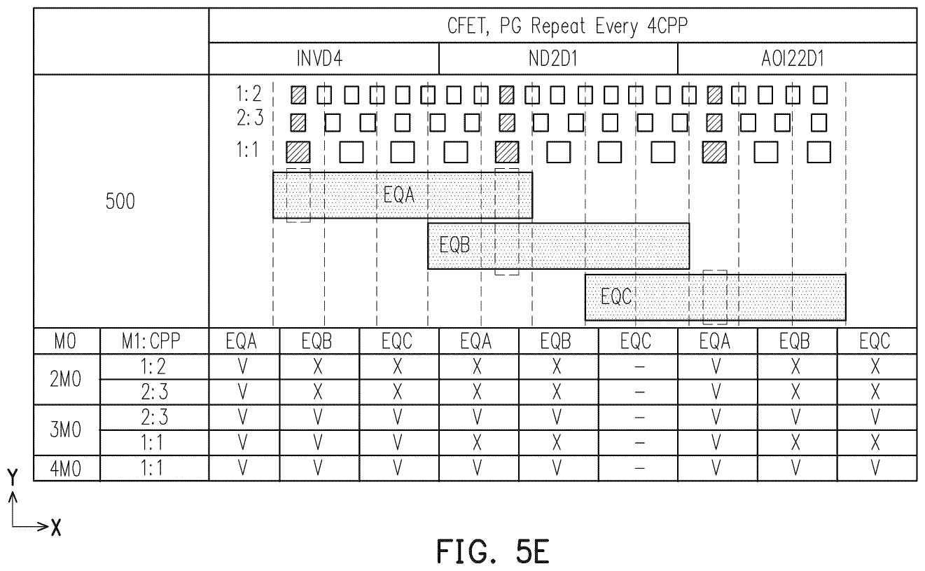

Each of IC layout diagrams/structures 400A and 400B is thereby capable of being included in a cell diagram of a cell usable in an IC layout diagram/structure based on IC layout diagram/structure 100H, as discussed below with respect to FIGS. 5A-5E.

FIGS. 5A-5E are diagrams of IC layout diagrams and corresponding IC structures, in accordance with some embodiments. Each of FIGS. 5A and 5E depicts an IC layout diagram/structure 500, each of FIGS. 5B and 5C depicts non-limiting examples of cell diagrams EQA, EQB, and EQC, and FIG. 5D depicts non-limiting examples of cell diagram EQA.

As depicted in FIG. 5A, IC layout diagram/structure 500 includes instances of frontside metal regions/lines M1 extending in the Y direction and configured to distribute reference voltage VSS, and instances of backside metal regions/lines BM1 extending in the Y direction and configured to distribute power supply voltage VDD, each discussed above.

A first row of IC layout diagram/structure 500 includes instances of cell diagram EQA corresponding to a logic function INVD1, e.g., an inverter, second and third rows include instances of cell diagrams EQA. EQB, and EQC corresponding to a logic function NR2D1, e.g., a NOR gate, and fourth and fifth rows include instances of cell diagrams EQA, EQB, and EQC corresponding to a logic function AOI22D1, e.g., an AND-OR-Invert logic gate. In some embodiments, an IC layout diagram/structure row is referred to as a CFET row.

In the non-limiting examples depicted in FIGS. 5A-5D, cell diagrams EQA, EQB, and EQC include signal pins, I, ZN, A1, A2, B1, and B2 corresponding to the example logic functions. Logic functions and signal pins other than those depicted in FIGS. 5A-5E, e.g., signal pins corresponding to various configurations of an inverter, NAND gate, NOR gate, XOR gate, latch, decoupling capacitor, and-or-invert (AOI), or-and-invert (OAI), multiplexer, flip-flop, or the like, are within the scope of the present disclosure.

Cell diagrams EQA, EQB, and EQC are EEQ cells for a given logic function in which each of cell diagrams EQA, EQB, and EQC corresponds to a placement of M1 Blockage region(s) at one or more locations along a dimension of the cell diagram extending in the X direction. As depicted in FIGS. 5B-5D, cell diagram EQA corresponds to embodiments in which an M1 Blockage region is adjacent to a leftmost cell border extending in the Y direction and at a most negative location in the X direction, cell diagram EQB corresponds to embodiments in which an M1 Blockage region is shifted from the leftmost border by one times pitch CPP, and cell diagram EQC corresponds to embodiments in which an M1 Blockage region is shifted from the leftmost border by two times pitch CPP.

The embodiments of cell diagrams EQA, EQB, and EQC depicted in FIGS. 5A-5E are non-limiting examples provided for the purpose of illustration. Other cell diagram embodiments including arrangements of M1 Blockage regions different from those depicted in FIGS. 5A-5E are within the scope of the present disclosure.

FIG. 5B depicts embodiments in which cell logic function AOI22D1 is implemented in each of cell diagrams EQA, EQB, and EQC including frontside (F/S) metal regions/lines M0 and backside (B/S) metal regions/lines BM0 positioned on a total of three tracks, and FIG. 5C depicts embodiments in which cell logic function AOI22D1 is implemented in each of cell diagrams EQA, EQB, and EQC including frontside (F/S) metal regions/lines M0 and backside (B/S) metal regions/lines BM0 positioned on a total of four tracks. Each of cell diagrams EQA, EQB, and EQC includes instances of a via region/structure VP (a single one labeled for the purpose of clarity) and instances of via region/structure VD.

Via regions/structures VP are positioned at locations corresponding to signal pin electrical connections to cell diagrams EQA, EQB, and EQC, and via regions/structures VD are positioned within M1 Blockage regions and are thereby configured to correspond to electrical connections through which power supply voltage VDD and reference voltage VSS are distributed to cell diagrams EQA, EQB, and EQC.

FIG. 5D depicts embodiments in which cell logic function AOI22D1 is implemented in cell diagram EQA. The signal pin electrical connections include a first configuration including only instances of frontside (F/S) metal regions/lines M1, a second configuration including only instances of backside (B/S) metal regions/lines BM1, and a third configuration including instances of both of frontside (F/S) metal regions/lines M1 and backside (B/S) metal regions/lines BM1.

FIG. 5E depicts IC layout diagram/structure 500 corresponding to various embodiments in which instances of metal regions/lines M1 configured to distribute reference voltage VSS (M1 Blockage) have a pitch equal to four times pitch CPP, metal regions/lines M0 have pitch values relative to cell height of 2M0, 3M0, or 4M0, and metal regions/lines M1 have overall pitch values relative to pitch CPP of 1:2, 2:3, or 1:1. The embodiment depicted in FIG. 5E includes cell diagrams EQA, EQB, and EQC corresponding to logic functions INVD4, ND2D1, and AOI22D1.

For each combination of logic function INVD4, ND2D1, and AOI22D1, cell diagram EQA, EQB, and EQC, and metal region/line M0 and M1 pitch value, FIG. 5E depicts an indicator V. X, or -. Indicator V corresponds to the locations of each instance of metal regions/lines M1 other than those corresponding to M1 Blockage being available for signal pin electrical connections, indicator X corresponds to the locations of a subset of the instances of metal regions/lines M1 other than those corresponding to M1 Blockage being available for signal pin electrical connections, and indicator-corresponds to the cell diagram, e.g., cell diagram EQC, not being applicable to the corresponding logic unction, e.g., logic function ND2D1.

Each of the embodiments of IC layout diagram/structure 500 is thereby configured to include instances of frontside metal region/line M1 and backside metal region/line BM1 configured as discussed above with respect to FIGS. 1A-1D such that the various embodiments of IC layout diagram/structure 500 are capable of realizing the benefits discussed above with respect to IC layout diagram/structure 100H.

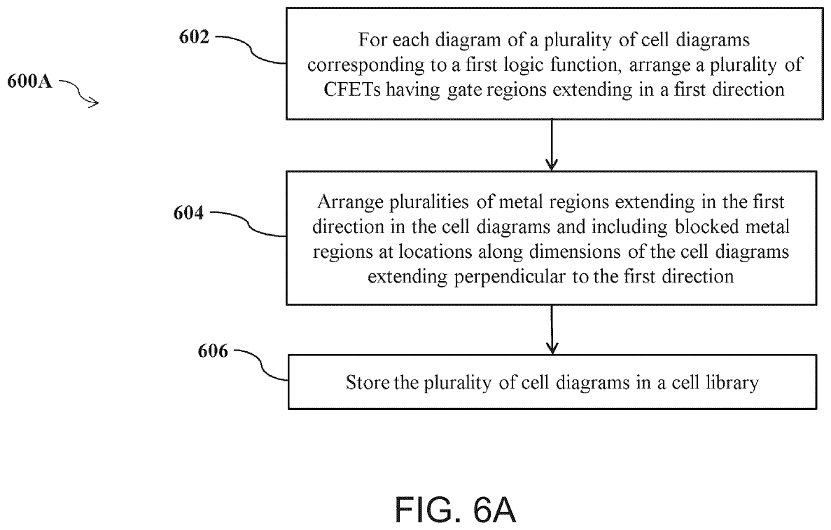

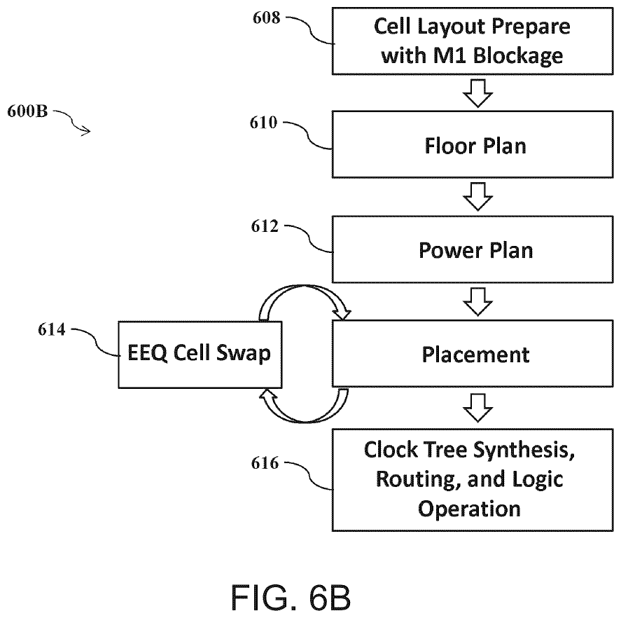

FIGS. 6A and 6B are flowcharts of methods 600A and 600B (referred to collectively as a method 600) of generating an IC layout diagram, in accordance with some embodiments. In some embodiments, generating the IC layout diagram includes generating some or all of one or more of IC layout diagrams 100H, 100V, 200, 300A-300C, 400A, 400B, or 500 discussed above with respect to FIGS. 1A-5E.

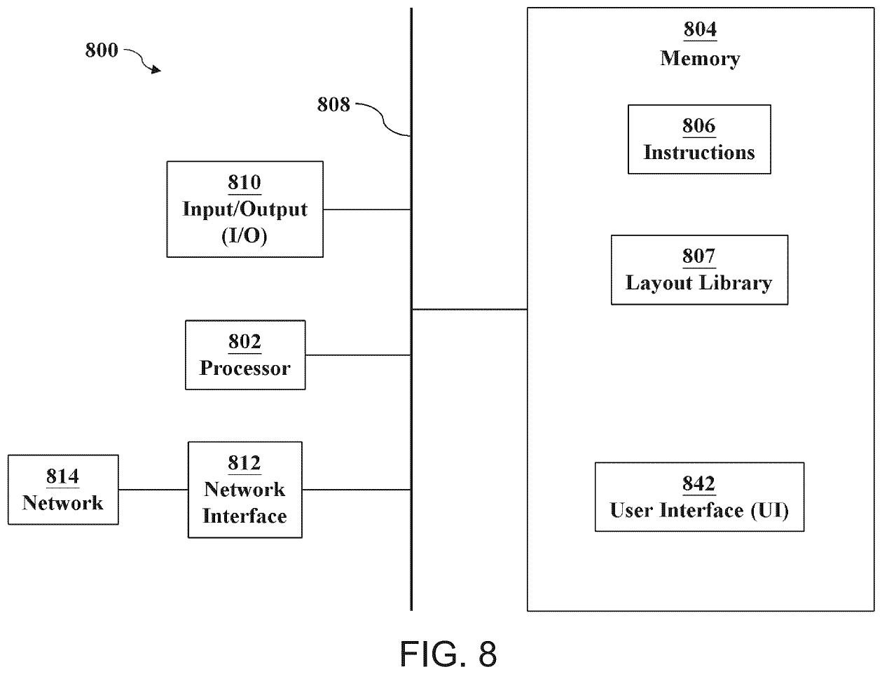

In some embodiments, some or all of method 600 is executed by a processor of a computer. In some embodiments, some or all of method 600 is executed by a processor 802 of IC layout diagram generation system 800, discussed below with respect to FIG. 8.

In some embodiments, one or more operations of method 600 are a subset of operations of a method of forming an IC device. In some embodiments, one or more operations of method 600 are a subset of operations of an IC manufacturing flow, e.g., the IC manufacturing flow discussed below with respect to manufacturing system 900 and FIG. 9.

In some embodiments, the operations of method 600 are performed in the order depicted in FIGS. 6A and 6B. In some embodiments, the operations of method 600 are performed simultaneously and/or in an order other than the order depicted in FIGS. 6A and 6B. In some embodiments, one or more operations are performed before, between, during, and/or after performing one or more operations of method 600.

Method 600A is equivalent to optional operation 608 of method 600B such that methods 600A and 600B are capable of being performed separately or as a combined method 600.

At operation 602 of method 600A, for each diagram of a plurality of cell diagrams corresponding to a first logic function, a plurality of CFETs having gate regions extending in a first direction is arranged. In some embodiments, arranging the plurality of CFETs includes arranging instances of CFETs CFT having gate regions G extending in the Y direction, discussed above with respect to FIGS. 1A-5E.

The plurality of cell diagrams corresponding to the first logic function are EEQ cell diagrams. In some embodiments, arranging the plurality of CFETs for each diagram of a plurality of cell diagrams corresponding to a first logic function includes the plurality of diagrams corresponding to cell diagrams EQA, EQB, and EQC discussed above with respect to FIGS. 5A-5E.

In some embodiments, the plurality of cell diagrams correspond to the first logic function being one of an inverter, NAND gate, NOR gate, XOR gate, latch, decoupling capacitor, AOI, OAI, multiplexer, flip-flop, or the like.

At operation 604 of method 600A, pluralities of metal regions are arranged extending in the first direction in the cell diagrams and including blocked metal regions at locations along dimensions of the cell diagrams extending perpendicular to the first direction.

Arranging the pluralities of metal regions extending in the first direction includes arranging the pluralities of metal regions in a lowest metal layer in which metal lines are aligned with the gate regions, e.g., based on a plurality of metal line tracks.

In various embodiments, arranging the pluralities of metal regions extending in the first direction includes arranging the pluralities of metal regions on one or both of a frontside or a backside of a semiconductor wafer.

In some embodiments, arranging the pluralities of metal regions extending in the first direction includes arranging instances of metal regions M0 extending in the Y direction discussed above with respect to FIGS. 1C and 1D.

In some embodiments, arranging the pluralities of metal regions extending in the first direction includes arranging instances of first metal regions extending perpendicular to the first direction and overlapping the gate regions, and arranging instances of second metal regions extending in the first direction. In some embodiments, arranging the instances of first and second metal regions includes arranging instances of metal regions M0 extending in the X direction and instances of metal regions M1 extending in the Y direction discussed above with respect to FIGS. 1A and 1B.

In some embodiments, arranging the pluralities of metal regions including blocked metal regions at locations along dimensions of the cell diagrams extending perpendicular to the first direction includes arranging instances of metal regions M1 in accordance with IC layout diagram 400B discussed above with respect to FIG. 4B and including blocked regions M1 Blockage in accordance with IC layout diagram 400A discussed above with respect to FIG. 4A.

In some embodiments, arranging the pluralities of metal regions extending in the first direction in the cell diagrams and including blocked metal regions at locations along dimensions of the cell diagrams extending perpendicular to the first direction includes arranging pluralities of metal regions M1 and BM1 extending in the Y direction including blocked metal regions at locations along dimensions of cell diagrams EQA, EQB, and EQC in the X direction in accordance with IC layout diagram 500 discussed above with respect to FIGS. 5A-5E.

At operation 606 of method 600A, the plurality of cell diagrams is stored in a cell library. In some embodiments, storing the plurality of cell diagrams in the cell library includes storing the IC layout diagram in an IC layout diagram library, e.g., layout diagram library 807 of IC layout diagram generation system 800, discussed below with respect to FIG. 8.

In some embodiments, storing the plurality of cell diagrams in the cell library includes storing the IC layout diagram in a non-volatile, computer-readable memory and/or a database and/or includes storing the plurality of cell diagrams over a network. In some embodiments, storing the plurality of cell diagrams in the cell library includes storing the plurality of cell diagrams over network 814 of IC layout diagram generation system 800, discussed below with respect to FIG. 8.

In some embodiments, the first logic function is one logic function of a plurality of logic functions, and each of operations 602-606 is repeated for each logic function of the plurality of logic functions.

At operation 608 of method 600B, in some embodiments, operations 602-606 of method 600A discussed above are performed, e.g., including preparing cell layouts with M1 Blockage.

At operation 610, in some embodiments, a floor plan of the IC layout diagram is arranged, e.g., in accordance with high level design criteria of an IC device corresponding to the IC layout diagram. In some embodiments, arranging the floor plan includes defining a CFET gate direction, e.g., the Y direction discussed above with respect to FIGS. 1A-5E.

At operation 612, a power plan of the IC layout diagram is arranged. Arranging the power plan includes aligning a power grid with the IC floor plan, wherein the power grid includes first power distribution lines aligned with a first plurality of tracks extending in a CFET gate direction of the IC floor plan.

In some embodiments, the first plurality of tracks corresponds to a metal layer of one of a frontside or a backside of an IC design corresponding to the IC layout diagram, and the metal layer is a lowest metal layer of the IC design including tracks extending in the CFET gate direction.

In some embodiments, arranging the power grid includes arranging the first power distribution lines including instances of metal regions M1 and/or BM1 extending in the Y direction discussed above with respect to FIGS. 1A and 1B or instances of metal regions M0 and/or BM0 extending in the Y direction discussed above with respect to FIGS. 1C and 1D.

In various embodiments, arranging the power grid includes arranging the first power distribution lines including instances of metal regions M1 and/or BM1 extending in the Y direction in accordance with one or more of IC layout diagrams 200, 300A-300C, or 500 discussed above with respect to FIGS. 2-5E.

In some embodiments, arranging the power grid includes determining a pitch of the first power distribution lines relative to a pitch of the CFET gate regions, e.g., pitch CPP discussed above. In some embodiments, determining the first power distribution line pitch includes applying a maximum voltage drop tolerance based on design criteria and parasitic resistance values of metal regions/lines M0 and/or BM0.

At operation 614, a cell diagram of the cell library is placed in the floor plan by matching a blocked site of the cell diagram with a track of the first plurality of tracks. Placing the cell diagram includes placing the cell diagram being one cell diagram of a plurality of EEQ cell diagrams corresponding to a logic function.

In some embodiments, placing the cell diagram is performed in accordance with one or more of IC layout diagrams 200, 300A-300C, or 500 discussed above with respect to FIGS. 2-5E. In some embodiments placing the cell diagram includes placing one of cell diagrams EQA, EQB, or EQC by matching M1 Blockage with one or more instances of metal regions M1 and/or BM1 discussed above with respect to FIGS. 5A-5E.

In some embodiments, placing the cell diagram includes swapping a first cell diagram with a second cell diagram, e.g., as part of an iterative design flow or engineering change order (ECO). In some embodiments, placing the cell diagram in the floor plan is part of an automatic placement and routing (APR) process or algorithm.

In some embodiments, placing the cell diagram of the cell library includes retrieving the cell diagram from IC library 807 of IC layout design system 800 discussed below with respect to FIG. 8.

At operation 616, in some embodiments, one or more additional design and/or manufacturing operations, e.g., clock tree synthesis (CTS), metal line routing, logic operations, or the like, are performed and the IC layout diagram is modified accordingly.

In some embodiments, performing the metal line routing operation includes routing an electrical connection to a pin of the cell diagram, e.g., an instance of metal region M1 or BM1, wherein the pin extends in the CFET gate direction.

In some embodiments, performing the additional design operations includes storing the IC layout diagram in a storage device. In some embodiments, storing the IC layout diagram in the storage device includes storing the IC layout diagram in an IC layout diagram library, e.g., layout library 807 of IC layout diagram generation system 800, discussed below with respect to FIG. 8.

In some embodiments, storing the IC layout diagram in the storage device includes storing the IC layout diagram in a non-volatile, computer-readable memory or a cell library, e.g., a database, and/or includes storing the IC layout diagram over a network. In some embodiments, storing the IC layout diagram in the storage device includes storing the IC layout diagram over network 814 of IC layout diagram generation system 800, discussed below with respect to FIG. 8.

In some embodiments, performing the one or more manufacturing operations includes performing one or more lithographic exposures based on the IC layout diagram. Performing one or more manufacturing operations, e.g., one or more lithographic exposures, based on the IC layout diagram is discussed below with respect to FIG. 9.

By executing some or all of the operations of method 600, an IC layout diagram is generated including instances of frontside metal regions/lines M0 or M1 and/or backside metal regions/lines BM0 or BM1 configured as discussed above with respect to FIGS. 1A-5E such that the various embodiments of the IC layout diagram are capable of realizing the benefits discussed above.

FIG. 7 is a flowchart of method 700 of manufacturing an IC device, in accordance with some embodiments. Method 700 is operable to form one or more of IC devices 100H, 100V, 200, 300A-300C, 400A, 400B, or 500 discussed above with respect to FIGS. 1A-5E.

In some embodiments, the operations of method 700 are performed in the order depicted in FIG. 7. In some embodiments, the operations of method 700 are performed in an order other than the order depicted in FIG. 7. In some embodiments, one or more additional operations are performed before, during, and/or after the operations of method 700. In some embodiments, performing some or all of the operations of method 700 includes performing one or more operations as discussed below with respect to IC manufacturing system 900 and FIG. 9.

At operation 702, in some embodiments, first and second CFETs are formed in a semiconductor wafer. Forming each of the first and second CFETs includes forming an n-type channel extending in a first direction, forming a p-type channel extending in the first direction and aligned with the n-type channel in a second direction perpendicular to the first direction, and forming a gate structure around each of the n-type channel and the p-type channel and extending in a third direction perpendicular to each of the first and second directions.

In some embodiments, forming the gate structure of one or both of the first or second CFETs includes forming a dummy gate structure, e.g., dummy gate structure DG discussed above with respect to FIGS. 1A-5E, adjacent to the one or both of the first or second CFETs.

In some embodiments, forming the first and second CFETs includes forming instances of CFETs CFT in semiconductor wafer 100W in accordance with one or more of IC layout diagrams/structures 100H, 100V, 200, 300A-300C, 400A, 400B, or 500 discussed above with respect to FIGS. 1A-5E.

In some embodiments, forming the first and second CFETs includes forming the first CFET in a first row and the second CFET in a second row, e.g., in accordance with the embodiments discussed above with respect to FIGS. 3A-5E.

In various embodiments, forming the first and second CFETs includes performing a plurality of manufacturing operations, e.g., one or more of a lithography, diffusion, deposition, etching, planarizing, or other operation suitable for depositing and forming one or more active areas, gate, S/D, and via structures configured as discussed above with respect to FIGS. 1A-5E.

At operation 704, a first metal line extending in a CFET gate direction and aligned with each of the first and second CFETs is constructed. Constructing the first metal line includes forming a first electrical connection to each of the first and second CFETs by constructing the first metal line on one of a frontside or a backside of the semiconductor wafer, and constructing the first metal line before or concurrently with constructing any other metal lines extending in the first direction on the one of the frontside or the backside of the semiconductor wafer.

In some embodiments, forming the first electrical connection to each of the first and second CFETs includes constructing a second metal line extending in the first direction between the first metal line and the first CFET and constructing a third metal line extending in the first direction between the first metal line and the second CFET.

In some embodiments, constructing the first metal line includes constructing an instance of metal lines M0, BM0, M1, or BM1 in accordance with one or more of the embodiments discussed above with respect to FIGS. 1A-5E.

In some embodiments, constructing the first metal line includes constructing the first metal line offset from the gate structure or adjacent dummy gate structure of each of the first and second CFETs in the first direction.

In some embodiments, constructing the first metal line includes constructing the first metal line aligned with the gate structure or adjacent dummy gate structure of each of the first and second CFETs in the second direction.

In various embodiments, constructing the first metal line includes performing a plurality of manufacturing operations, e.g., one or more of a lithography, diffusion, deposition, etching, planarizing, or other operation suitable for constructing isolation structures in accordance with the configurations discussed above with respect to FIGS. 1A-5E.

At operation 706, in some embodiments, a second metal line extending in the CFET gate direction and aligned with each of the first and second CFETs is constructed. Constructing the second metal line includes forming a second electrical connection to each of the first and second CFETs by constructing the second metal line on the other of the frontside or the backside of the semiconductor wafer, and constructing the second metal line before or concurrently with constructing any other metal lines extending in the first direction on the other of the frontside or the backside of the semiconductor wafer.

In some embodiments, constructing the second metal line includes constructing an instance of metal lines M0, BM0, M1, or BM1 in accordance with one or more of the embodiments discussed above with respect to FIGS. 1A-5E.

In various embodiments, constructing the second metal line includes performing a plurality of manufacturing operations, e.g., one or more of a lithography, diffusion, deposition, etching, planarizing, or other operation suitable for constructing metal lines in accordance with the configurations discussed above with respect to FIGS. 1A-5E.

At operation 708, in some embodiments, first and second power grids electrically connected to the first and second metal lines are constructed. Constructing the first and second power grids includes constructing the first power grid electrically connected to the first metal line and configured to distribute one of a power supply voltage or a reference voltage and constructing the second power grid electrically connected to the second metal line and configured to distribute the other of the power supply voltage or the reference voltage.

In some embodiments, constructing the first and second power grids includes configuring the first and second power grids to distribute power supply voltage VDD and reference voltage VSS discussed above with respect to FIGS. 1A-5E.

In various embodiments, constructing the first and second power grids includes performing a plurality of manufacturing operations, e.g., one or more of a lithography, diffusion, deposition, etching, planarizing, or other operation suitable for constructing vias and metal segments.

By performing some or all of the operations of method 700, an IC structure is formed instances of frontside metal lines M0 or M1 and/or backside metal lines BM0 or BM1 configured as discussed above with respect to FIGS. 1A-5E such that the various embodiments of the IC structure are capable of realizing the benefits discussed above.

FIG. 8 is a block diagram of IC layout diagram generation system 800, in accordance with some embodiments. Methods of designing IC layout diagrams in accordance with one or more embodiments described herein are implementable, for example, using IC layout diagram generation system 800, in accordance with some embodiments.

In some embodiments, IC layout diagram generation system 800 is a general purpose computing device including a hardware processor 802 and a non-transitory, computer-readable storage medium 804. Storage medium 804, amongst other things, is encoded with, i.e., stores, computer program code 806, i.e., a set of executable instructions. Execution of instructions 806 by hardware processor 802 represents (at least in part) an EDA tool which implements a portion or all of a method, e.g., one or both of methods 600A or 600B described herein with respect to FIGS. 1A-6B (hereinafter, the noted processes and/or methods).

Processor 802 is electrically coupled to computer-readable storage medium 804 via a bus 808. Processor 802 is also electrically coupled to an I/O interface 810 by bus 808. A network interface 812 is also electrically connected to processor 802 via bus 808. Network interface 812 is connected to a network 814, so that processor 802 and computer-readable storage medium 804 are capable of connecting to external elements via network 814. Processor 802 is configured to execute computer program code 806 encoded in computer-readable storage medium 804 in order to cause IC layout diagram generation system 800 to be usable for performing a portion or all of the noted processes and/or methods. In one or more embodiments, processor 802 is a central processing unit (CPU), a multi-processor, a distributed processing system, an application specific integrated circuit (ASIC), and/or a suitable processing unit.

In one or more embodiments, computer-readable storage medium 804 is an electronic, magnetic, optical, electromagnetic, infrared, and/or a semiconductor system (or apparatus or device). For example, computer-readable storage medium 804 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 804 includes a compact disk-read only memory (CD-ROM), a compact disk-read/write (CD-R/W), and/or a digital video disc (DVD).

In one or more embodiments, storage medium 804 stores computer program code 806 configured to cause IC layout diagram generation system 800 (where such execution represents (at least in part) the EDA tool) to be usable for performing a portion or all of the noted processes and/or methods. In one or more embodiments, storage medium 804 also stores information which facilitates performing a portion or all of the noted processes and/or methods. In one or more embodiments, storage medium 804 stores a layout library 807, also referred to as a cell library 807 in some embodiments, including such layouts as disclosed herein, e.g., one or more of IC layout diagrams 100H, 100V, 200, 300A-300C, 400A, 400B, or 500 discussed above with respect to FIGS. 1A-5E.

IC layout diagram generation system 800 includes I/O interface 810. I/O interface 810 is coupled to external circuitry. In one or more embodiments, I/O interface 810 includes a keyboard, keypad, mouse, trackball, trackpad, touchscreen, and/or cursor direction keys for communicating information and commands to processor 802.

IC layout diagram generation system 800 also includes network interface 812 coupled to processor 802. Network interface 812 allows system 800 to communicate with network 814, to which one or more other computer systems are connected. Network interface 812 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more IC layout diagram generation systems 800.

IC layout diagram generation system 800 is configured to receive information through I/O interface 810. The information received through I/O interface 810 includes one or more of instructions, data, design rules, libraries of standard cells, and/or other parameters for processing by processor 802. The information is transferred to processor 802 via bus 808. IC layout diagram generation system 800 is configured to receive information related to a UI through I/O interface 810. The information is stored in computer-readable medium 804 as user interface (UI) 842.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by IC layout diagram generation system 800. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

FIG. 9 is a block diagram of IC manufacturing system 900, and an IC manufacturing flow associated therewith, in accordance with some embodiments. In some embodiments, based on an IC layout diagram, at least one of (A) one or more semiconductor masks or (B) at least one component in a layer of a semiconductor integrated circuit is fabricated using manufacturing system 900.

In FIG. 9. IC manufacturing system 900 includes entities, such as a design house 920, a mask house 930, and an IC manufacturer/fabricator (“fab”) 950, that interact with one another in the design, development, and manufacturing cycles and/or services related to manufacturing an IC device 960. The entities in system 900 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 920, mask house 930, and IC fab 950 is owned by a single larger company. In some embodiments, two or more of design house 920, mask house 930, and IC fab 950 coexist in a common facility and use common resources.

Design house (or design team) 920 generates an IC design layout diagram 922. IC design layout diagram 922 includes various geometrical patterns, e.g., one or more of IC layout diagrams 100H, 100V, 200, 300A-300C, 400A, 400B, or 500 discussed above with respect to FIGS. 1A-5E. The geometrical patterns correspond to patterns of metal, oxide, or semiconductor layers that make up the various components of IC device 960 to be fabricated. The various layers combine to form various IC features. For example, a portion of IC design layout diagram 922 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 920 implements a proper design procedure to form IC design layout diagram 922. The design procedure includes one or more of logic design, physical design or place and route. IC design layout diagram 922 is presented in one or more data files having information of the geometrical patterns. For example, IC design layout diagram 922 can be expressed in a GDSII file format or DFII file format.

Mask house 930 includes data preparation 932 and mask fabrication 944. Mask house 930 uses IC design layout diagram 922 to manufacture one or more masks 945 to be used for fabricating the various layers of IC device 960 according to IC design layout diagram 922. Mask house 930 performs mask data preparation 932, where IC design layout diagram 922 is translated into a representative data file (“RDF”). Mask data preparation 932 provides the RDF to mask fabrication 944. Mask fabrication 944 includes a mask writer. A mask writer converts the RDF to an image on a substrate, such as a mask (reticle) 945 or a semiconductor wafer 953, e.g., semiconductor wafer 100W discussed above with respect to FIGS. 1A-5E. The design layout diagram 922 is manipulated by mask data preparation 932 to comply with particular characteristics of the mask writer and/or requirements of IC fab 950. In FIG. 9, mask data preparation 932 and mask fabrication 944 are illustrated as separate elements. In some embodiments, mask data preparation 932 and mask fabrication 944 can be collectively referred to as mask data preparation.

In some embodiments, mask data preparation 932 includes optical proximity correction (OPC) which uses lithography enhancement techniques to compensate for image errors, such as those that can arise from diffraction, interference, other process effects and the like. OPC adjusts IC design layout diagram 922. In some embodiments, mask data preparation 932 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 932 includes a mask rule checker (MRC) that checks the IC design layout diagram 922 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 922 to compensate for limitations during mask fabrication 944, which may undo part of the modifications performed by OPC in order to meet mask creation rules.

In some embodiments, mask data preparation 932 includes lithography process checking (LPC) that simulates processing that will be implemented by IC fab 950 to fabricate IC device 960. LPC simulates this processing based on IC design layout diagram 922 to create a simulated manufactured device, such as IC device 960. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 922.

It should be understood that the above description of mask data preparation 932 has been simplified for the purposes of clarity. In some embodiments, data preparation 932 includes additional features such as a logic operation (LOP) to modify the IC design layout diagram 922 according to manufacturing rules. Additionally, the processes applied to IC design layout diagram 922 during data preparation 932 may be executed in a variety of different orders.

After mask data preparation 932 and during mask fabrication 944, a mask 945 or a group of masks 945 are fabricated based on the modified IC design layout diagram 922. In some embodiments, mask fabrication 944 includes performing one or more lithographic exposures based on IC design layout diagram 922. In some embodiments, an electron-beam (e-beam) or a mechanism of multiple e-beams is used to form a pattern on a mask (photomask or reticle) 945 based on the modified IC design layout diagram 922. Mask 945 can be formed in various technologies. In some embodiments, mask 945 is formed using binary technology. In some embodiments, a mask pattern includes opaque regions and transparent regions. A radiation beam, such as an ultraviolet (UV) or EUV beam, used to expose the image sensitive material layer (e.g., photoresist) which has been coated on a wafer, is blocked by the opaque region and transmits through the transparent regions. In one example, a binary mask version of mask 945 includes a transparent substrate (e.g., fused quartz) and an opaque material (e.g., chromium) coated in the opaque regions of the binary mask. In another example, mask 945 is formed using a phase shift technology. In a phase shift mask (PSM) version of mask 945, various features in the pattern formed on the phase shift mask are configured to have proper phase difference to enhance the resolution and imaging quality. In various examples, the phase shift mask can be attenuated PSM or alternating PSM. The mask(s) generated by mask fabrication 944 is used in a variety of processes. For example, such a mask(s) is used in an ion implantation process to form various doped regions in semiconductor wafer 953, in an etching process to form various etching regions in semiconductor wafer 953, and/or in other suitable processes.

IC fab 950 is an IC fabrication business that includes one or more manufacturing facilities for the fabrication of a variety of different IC products. In some embodiments, IC Fab 950 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 950 includes wafer fabrication tools 952 configured to execute various manufacturing operations on semiconductor wafer 953 such that IC device 960 is fabricated in accordance with the mask(s), e.g., mask 945. In various embodiments, fabrication tools 952 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 950 uses mask (s) 945 fabricated by mask house 930 to fabricate IC device 960. Thus, IC fab 950 at least indirectly uses IC design layout diagram 922 to fabricate IC device 960. In some embodiments, semiconductor wafer 953 is fabricated by IC fab 950 using mask(s) 945 to form IC device 960. In some embodiments, the IC fabrication includes performing one or more lithographic exposures based at least indirectly on IC design layout diagram 922. Semiconductor wafer 953 includes a silicon substrate or other proper substrate having material layers formed thereon. Semiconductor wafer 953 further includes one or more of various doped regions, dielectric features, multilevel interconnects, and the like (formed at subsequent manufacturing steps).

In some embodiments, an IC structure includes first and second CFETs positioned in a semiconductor wafer, wherein each of the first and second CFETs includes a gate structure extending in a first direction, an n-type channel extending through the gate structure in a second direction perpendicular to the first direction, and a p-type channel extending through the gate structure in the second direction and aligned with the n-type channel in a third direction perpendicular to each of the first and second directions, and a first metal line extending in the first direction and aligned with each of the first and second CFETs in the third direction, wherein the first metal line is configured to distribute one of a power supply voltage or a reference voltage to each of the first and second CFETs, and the first metal line is a metal line closest to each of the first and second CFETs along the third direction and extending in the first direction. In some embodiments, the IC structure includes second and third metal lines extending in the second direction, wherein the first CFET is electrically connected to the first metal line through the second metal line and the second CFET is electrically connected to the first metal line through the third metal line. In some embodiments, the first metal line is positioned on a frontside of the semiconductor wafer. In some embodiments, the IC structure includes a second metal line extending in the first direction on a backside of the semiconductor wafer and aligned with each of the first and second CFETs in the third direction, wherein the second metal line is configured to distribute the other of the power supply voltage or the reference voltage to each of the first and second CFETs, and the second metal line is a backside metal line closest to each of the first and second CFETs along the third direction and extending in the first direction. In some embodiments, the first CFET is positioned in a first CFET row extending in the second direction, the second CFET is positioned in a second CFET row extending in the second direction, the first metal line is a first metal line of a first plurality of metal lines extending in the first direction in a same metal layer of the IC, and each metal line of the first plurality of metal lines is configured to distribute the one of the power supply voltage or the reference voltage to a corresponding CFET in each of the first and second CFET rows. In some embodiments, the first plurality of metal lines has a pitch in the first direction equal to a multiple of a pitch of the gate structures of the first and second CFET rows. In some embodiments, the multiple is equal to four. In some embodiments, subsets of CFETs of each of the first and second CFET rows are separated by dummy gate structures positioned at locations corresponding to the pitch of the gate structures, and the metal lines of the first plurality of metal lines are positioned between adjacent instances of gate structures or between instances of gate structures and adjacent dummy gate structures. In some embodiments, subsets of CFETs of each of the first and second CFET rows are separated by dummy gate structures positioned at locations corresponding to the pitch of the gate structures, and the metal lines of the first plurality of metal lines are aligned with instances of the gate structures and/or the dummy gate structures along the third direction. In some embodiments, the IC structure includes second pluralities of metal lines extending in the first direction in the same metal layer of the IC and positioned entirely in the first CFET row between adjacent metal lines of the first plurality of metal lines and third pluralities of metal lines extending in the first direction in the same metal layer of the IC and positioned entirely in the second CFET row between adjacent metal lines of the first plurality of metal lines.

In some embodiments, a method of manufacturing an IC structure includes forming first and second CFETs in a semiconductor wafer, wherein the forming each of the first and second CFETs includes forming an n-type channel extending in a first direction, forming a p-type channel extending in the first direction and aligned with the n-type channel in a second direction perpendicular to the first direction, and forming a gate structure around each of the n-type channel and the p-type channel and extending in a third direction perpendicular to each of the first and second directions, and constructing a first metal line extending in the third direction and aligned with each of the first and second CFETs in the second direction, wherein constructing the first metal line includes forming a first electrical connection to each of the first and second CFETs by constructing the first metal line on one of a frontside or a backside of the semiconductor wafer, and constructing the first metal line before or concurrently with constructing any other metal lines extending in the first direction on the one of the frontside or the backside of the semiconductor wafer. In some embodiments, forming the first electrical connection to each of the first and second CFETs includes constructing a second metal line extending in the first direction between the first metal line and the first CFET and constructing a third metal line extending in the first direction between the first metal line and the second CFET. In some embodiments, the method includes constructing a second metal line extending in the third direction and aligned with each of the first and second CFETs in the second direction, wherein constructing the second metal line includes forming a second electrical connection to each of the first and second CFETs by constructing the second metal line on the other of the frontside or the backside of the semiconductor wafer, and constructing the second metal line before or concurrently with constructing any other metal lines extending in the first direction on the other of the frontside or the backside of the semiconductor wafer. In some embodiments, the method includes constructing a first power grid electrically connected to the first metal line and configured to distribute one of a power supply voltage or a reference voltage and constructing a second power grid electrically connected to the second metal line and configured to distribute the other of the power supply voltage or the reference voltage. In some embodiments, forming the gate structure of one or both of the first or second CFETs includes forming a dummy gate structure adjacent to the one or both of the first or second CFETs, and constructing the first metal line includes constructing the first metal line offset from the gate structure or adjacent dummy gate structure of each of the first and second CFETs in the first direction. In some embodiments, forming the gate structure of one or both of the first or second CFETs includes forming a dummy gate structure adjacent to the one or both of the first or second CFETs, and constructing the first metal line includes constructing the first metal line aligned with the gate structure or adjacent dummy gate structure of each of the first and second CFETs in the second direction.

In some embodiments, a method of generating an IC layout diagram includes aligning a power grid with an IC floor plan, wherein the power grid includes first power distribution lines aligned with a first plurality of tracks extending in a CFET gate direction of the IC floor plan, placing a cell diagram of a cell library in the floor plan by matching a blocked site of the cell diagram with a track of the first plurality of tracks, and routing an electrical connection to a pin of the cell diagram, wherein the pin extends in the CFET gate direction. In some embodiments, the first plurality of tracks corresponds to a metal layer of one of a frontside or a backside of an IC design corresponding to the IC layout diagram, and the metal layer is a lowest metal layer of the IC design comprising tracks extending in the CFET gate direction. In some embodiments, the first plurality of tracks corresponds to a metal layer of one of a frontside or a backside of an IC design corresponding to the IC layout diagram, the power grid includes second power distribution lines aligned with a second plurality of tracks extending in the CFET gate direction and corresponding to the other of the frontside or the backside of the IC design, and placing the cell diagram in the floor plan includes matching another blocked site of the cell diagram with a track of the second plurality of tracks. In some embodiments, the first power distribution lines correspond to a first portion of the power grid configured to distribute a reference voltage on the frontside of the IC design, and the second power distribution lines correspond to a second portion of the power grid configured to distribute a power supply voltage on the backside of the IC design.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. An integrated circuit (IC) structure comprising:
first and second complementary field-effect transistors (CFETs) positioned in a semiconductor wafer, wherein each of the first and second CFETs comprises:
a gate structure extending in a first direction;
an n-type channel extending through the gate structure in a second direction perpendicular to the first direction; and
a p-type channel extending through the gate structure in the second direction and aligned with the n-type channel in a third direction perpendicular to each of the first and second directions; and
a first metal line extending in the first direction and aligned with each of the first and second CFETs in the third direction,
wherein
the first metal line is configured to distribute one of a power supply voltage or a reference voltage to each of the first and second CFETs, and
the first metal line is a metal line closest to each of the first and second CFETs along the third direction and extending in the first direction.

2. The IC structure of claim 1, further comprising second and third metal lines extending in the second direction, wherein
the first CFET is electrically connected to the first metal line through the second metal line, and
the second CFET is electrically connected to the first metal line through the third metal line.

3. The IC structure of claim 1, wherein the first metal line is positioned on a frontside of the semiconductor wafer.

4. The IC structure of claim 3, further comprising:
a second metal line extending in the first direction on a backside of the semiconductor wafer and aligned with each of the first and second CFETs in the third direction,
wherein
the second metal line is configured to distribute the other of the power supply voltage or the reference voltage to each of the first and second CFETs, and
the second metal line is a backside metal line closest to each of the first and second CFETs along the third direction and extending in the first direction.

5. The IC structure of claim 1, wherein
the first CFET is positioned in a first CFET row extending in the second direction,
the second CFET is positioned in a second CFET row extending in the second direction,
the first metal line is a first metal line of a first plurality of metal lines extending in the first direction in a same metal layer of the IC structure, and
each metal line of the first plurality of metal lines is configured to distribute the one of the power supply voltage or the reference voltage to a corresponding CFET in each of the first and second CFET rows.

6. The IC structure of claim 5, wherein
the first plurality of metal lines has a pitch in the first direction equal to a multiple of a pitch of the gate structures of the first and second CFET rows.

7. The IC structure of claim 6, wherein the multiple is equal to four.

8. The IC structure of claim 5, wherein
subsets of CFETs of each of the first and second CFET rows are separated by dummy gate structures positioned at locations corresponding to the pitch of the gate structures, and
the metal lines of the first plurality of metal lines are positioned between adjacent instances of gate structures or between instances of gate structures and adjacent dummy gate structures.

9. The IC structure of claim 5, wherein
subsets of CFETs of each of the first and second CFET rows are separated by dummy gate structures positioned at locations corresponding to the pitch of the gate structures, and
the metal lines of the first plurality of metal lines are aligned with instances of the gate structures and/or the dummy gate structures along the third direction.

10. The IC structure of claim 5, further comprising:
second pluralities of metal lines extending in the first direction in the same metal layer of the IC structure and positioned entirely in the first CFET row between adjacent metal lines of the first plurality of metal lines; and
third pluralities of metal lines extending in the first direction in the same metal layer of the IC structure and positioned entirely in the second CFET row between adjacent metal lines of the first plurality of metal lines.

11. A method of manufacturing an integrated circuit (IC) structure, the method comprising:
forming first and second complementary field-effect transistors (CFETs) in a semiconductor wafer, wherein the forming each of the first and second CFETs comprises:
forming an n-type channel extending in a first direction;
forming a p-type channel extending in the first direction and aligned with the n-type channel in a second direction perpendicular to the first direction; and
forming a gate structure around each of the n-type channel and the p-type channel and extending in a third direction perpendicular to each of the first and second directions; and
constructing a first metal line extending in the third direction and aligned with each of the first and second CFETs in the second direction,
wherein the constructing the first metal line comprises:
forming a first electrical connection to each of the first and second CFETs by constructing the first metal line on one of a frontside or a backside of the semiconductor wafer, and
constructing the first metal line before or concurrently with constructing any other metal lines extending in the first direction on the one of the frontside or the backside of the semiconductor wafer.

12. The method of claim 11, wherein the forming the first electrical connection to each of the first and second CFETs comprises:
constructing a second metal line extending in the first direction between the first metal line and the first CFET, and
constructing a third metal line extending in the first direction between the first metal line and the second CFET.

13. The method of claim 11, further comprising:
constructing a second metal line extending in the third direction and aligned with each of the first and second CFETs in the second direction,
wherein the constructing the second metal line comprises:
forming a second electrical connection to each of the first and second CFETs by constructing the second metal line on the other of the frontside or the backside of the semiconductor wafer, and
constructing the second metal line before or concurrently with constructing any other metal lines extending in the first direction on the other of the frontside or the backside of the semiconductor wafer.

14. The method of claim 13, further comprising:
constructing a first power grid electrically connected to the first metal line and configured to distribute one of a power supply voltage or a reference voltage; and
constructing a second power grid electrically connected to the second metal line and configured to distribute the other of the power supply voltage or the reference voltage.

15. The method of claim 11, wherein
the forming the gate structure of one or both of the first or second CFETs comprises forming a dummy gate structure adjacent to the one or both of the first or second CFETs, and
the constructing the first metal line comprises constructing the first metal line offset from the gate structure or adjacent dummy gate structure of each of the first and second CFETs in the first direction.

16. The method of claim 11, wherein
the forming the gate structure of one or both of the first or second CFETs comprises forming a dummy gate structure adjacent to the one or both of the first or second CFETs, and
the constructing the first metal line comprises constructing the first metal line aligned with the gate structure or adjacent dummy gate structure of each of the first and second CFETs in the second direction.

17. A method of generating an integrated circuit (IC) layout diagram, the method comprising:
aligning a power grid with an IC floor plan, wherein the power grid comprises first power distribution lines aligned with a first plurality of tracks extending in a complementary field-effect transistor (CFET) gate direction of the IC floor plan;
placing a cell diagram of a cell library in the floor plan by matching a blocked site of the cell diagram with a track of the first plurality of tracks; and
routing an electrical connection to a pin of the cell diagram, wherein the pin extends in the CFET gate direction.

18. The method of claim 17, wherein
the first plurality of tracks corresponds to a metal layer of one of a frontside or a backside of an IC design corresponding to the IC layout diagram, and
the metal layer is a lowest metal layer of the IC design comprising tracks extending in the CFET gate direction.

19. The method of claim 17, wherein
the first plurality of tracks corresponds to a metal layer of one of a frontside or a backside of an IC design corresponding to the IC layout diagram,
the power grid comprises second power distribution lines aligned with a second plurality of tracks extending in the CFET gate direction and corresponding to the other of the frontside or the backside of the IC design, and
the placing the cell diagram in the floor plan comprises matching another blocked site of the cell diagram with a track of the second plurality of tracks.

20. The method of claim 19, wherein
the first power distribution lines correspond to a first portion of the power grid configured to distribute a reference voltage on the frontside of the IC design, and
the second power distribution lines correspond to a second portion of the power grid configured to distribute a power supply voltage on the backside of the IC design.
